(19) United States
(12) Patent Application Publication
(10) Pub. No.: US 2026/0076039 A1
(43) Pub. Date: Mar. 12, 2026

(54) DISPLAY DEVICE, ELECTRONIC DEVICE AND OPTICAL DEVICE

(71) Applicant: Samsung Display Co., Ltd., Yongin-si (KR)

(72) Inventor: Chun Gi YOU, Yongin-si (KR)

(21) Appl. No.: 19/213,872

(22) Filed: May 20, 2025

(30) Foreign Application Priority Data
Sep. 10, 2024 (KR) 10-2024-0122801

(51) Int. Cl. H10K 59/122

(52) U.S. Cl. CPC H10K 59/122

(57) ABSTRACT

The present disclosure relates to a display device capable of improving a recognition rate of an align key and an optical device, and including a substrate, a first electrode on the substrate, a pixel-defining layer above the first electrode, a light-emitting stack above the first electrode and the pixel-defining layer, a second electrode above the light-emitting stack, and an align key in a non-display area of the substrate, and including an outer pattern layer above the substrate, an inner pattern layer inside a through hole of the outer pattern layer, and a dummy layer between the outer pattern layer and the inner pattern layer.

### CROSS-REFERENCE TO RELATED APPLICATION

The present application claims priority to, and the benefit of, Korean Patent Application No. 10-2024-0122801, filed on Sep. 10, 2024, in the Korean Intellectual Property Office, the entire disclosure of which is incorporated herein by reference.

### BACKGROUND

### 1. Field

The present disclosure relates to a display device capable of improving a recognition rate of an align key, and an optical device.

### 2. Description of the Related Art

A head-mounted display (HMD) is an image display device that is worn on a user's head in the form of glasses or a helmet, and forms a focus at a distance relatively close to user's eyes in front of the user's eyes. The head-mounted display may implement virtual reality (VR) or augmented reality (AR).

The head-mounted display magnifies and displays an image displayed by a small display device using a plurality of lenses. Therefore, a display device applied to the head-mounted display needs to provide a high-resolution image, for example, an image having a resolution of about 3000 pixels per inch (PPI) or more. To this end, an organic light-emitting diode on silicon (OLEDoS), which is a small organic light-emitting display device having a high resolution, has been used as the display device applied to the head-mounted display. The OLEDoS is a device that displays an image by arranging organic light-emitting diodes (OLEDs) on a semiconductor wafer substrate on which complementary metal oxide semiconductors (CMOSs) are located.

### SUMMARY

Aspects of the present disclosure provide a display device capable of improving a recognition rate of an align key and an optical device.

According to an aspect of the present disclosure, there is provided a display device including a substrate, a first electrode on the substrate, a pixel-defining layer above the first electrode, a light-emitting stack above the first electrode and the pixel-defining layer, a second electrode above the light-emitting stack, and an align key in a non-display area of the substrate, and including an outer pattern layer above the substrate, an inner pattern layer inside a through hole of the outer pattern layer, and a dummy layer between the outer pattern layer and the inner pattern layer.

The outer pattern layer and the inner pattern layer may include metal, wherein the dummy layer includes a non-metal.

The inner pattern layer may be surrounded by the outer pattern layer in plan view.

The outer pattern layer may include a first sub-outer pattern layer, and a second sub-outer pattern layer above the first sub-outer pattern layer.

The inner pattern layer may include a first sub-inner pattern layer, and a second sub-inner pattern layer above the first sub-inner pattern layer.

The dummy layer may include a first sub-dummy layer, a second sub-dummy layer above the first sub-dummy layer, a third sub-dummy layer above the second sub-dummy layer, and a fourth sub-dummy layer above the third sub-dummy layer.

The first sub-dummy layer may be at least partially above the outer pattern layer and the inner pattern layer.

The fourth sub-dummy layer may be above the outer pattern layer and the inner pattern layer.

The through hole and the inner pattern layer may have a same shape.

The dummy layer may have a through hole overlapping the inner pattern layer.

In addition, according to an aspect of the present disclosure, there is provided an optical device including an optical-path-changing member, and a display device below the optical-path-changing member, and including a substrate, a first electrode above the substrate, a pixel-defining layer above the first electrode, a light-emitting stack above the first electrode and the pixel-defining layer, a second electrode above the light-emitting stack, and an align key in a non-display area of the substrate, and including an outer pattern layer above the substrate, an inner pattern layer inside a through hole of the outer pattern layer, and a dummy layer between the outer pattern layer and the inner pattern layer.

The outer pattern layer and the inner pattern layer may include metal, wherein the dummy layer includes a non-metal.

The inner pattern layer may be surrounded by the outer pattern layer in plan view.

The outer pattern layer may include a first sub-outer pattern layer, and a second sub-outer pattern layer above the first sub-outer pattern layer.

The inner pattern layer may include a first sub-inner pattern layer, and a second sub-inner pattern layer above the first sub-inner pattern layer.

The dummy layer may include a first sub-dummy layer, a second sub-dummy layer above the first sub-dummy layer, a third sub-dummy layer above the second sub-dummy layer, and a fourth sub-dummy layer above the third sub-dummy layer.

The first sub-dummy layer may be at least partially above the outer pattern layer and the inner pattern layer.

The fourth sub-dummy layer may be above the outer pattern layer and the inner pattern layer.

The through hole and the inner pattern layer may have a same shape.

In addition, according to an aspect of the present disclosure, there is provided an electronic device including a display device including a screen, a substrate, a first electrode above the substrate, a pixel-defining layer above the first electrode, a light-emitting stack above the first electrode and the pixel-defining layer, a second electrode above the light-emitting stack, and an align key in a non-display area of the substrate, and including an outer pattern layer above the substrate, an inner pattern layer inside a through hole of the outer pattern layer, and a dummy layer between the outer pattern layer and the inner pattern layer.

In accordance with a display device, a recognition rate of an align key may be improved.

It should be noted that the aspects of the disclosure may not be limited to those described above, and other aspects of the disclosure will be apparent from the following description.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view illustrating a display device according to one or more embodiments;

FIG. 2 is a block diagram illustrating the display device according to one or more embodiments;

FIG. 3 is an equivalent circuit diagram of a first sub-pixel according to one or more embodiments;

FIG. 4 is a layout diagram illustrating a display panel according to one or more embodiments;

FIG. 5 is a layout diagram illustrating a display area of FIG. 4;

FIG. 6 is a layout diagram illustrating a display area of FIG. 4 according to one or more other embodiments;

FIG. 7 is a cross-sectional view illustrating a display panel taken along the line I1-I1′ of FIG. 5;

FIG. 8 is a layout diagram illustrating a first pad of a first pad portion of FIG. 4;

FIG. 9 is a cross-sectional view illustrating a display panel taken along the line I2-I2′ of FIG. 8;

FIG. 10 is a plan view of an align key of FIG. 4;

FIG. 11 is a cross-sectional view illustrating a display panel taken along the line I3-I3′ of FIG. 10;

FIG. 12 is a cross-sectional view illustrating a display panel taken along the line I4-I4′ of FIG. 10;

FIG. 13 is a perspective view illustrating a head-mounted display device according to one or more embodiments;

FIG. 14 is an exploded perspective view illustrating the head-mounted display device of FIG. 13;

FIG. 15 is a perspective view illustrating a head-mounted display device according to one or more other embodiments;

FIG. 16 is a block diagram of an electronic device according to one or more embodiments; and

FIGS. 17, 18 and 19 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B. Similarly, expressions, such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially”has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

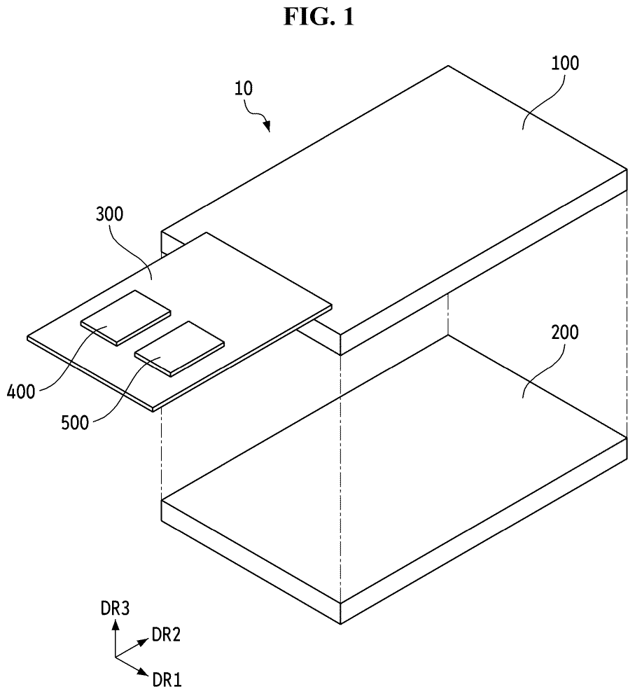

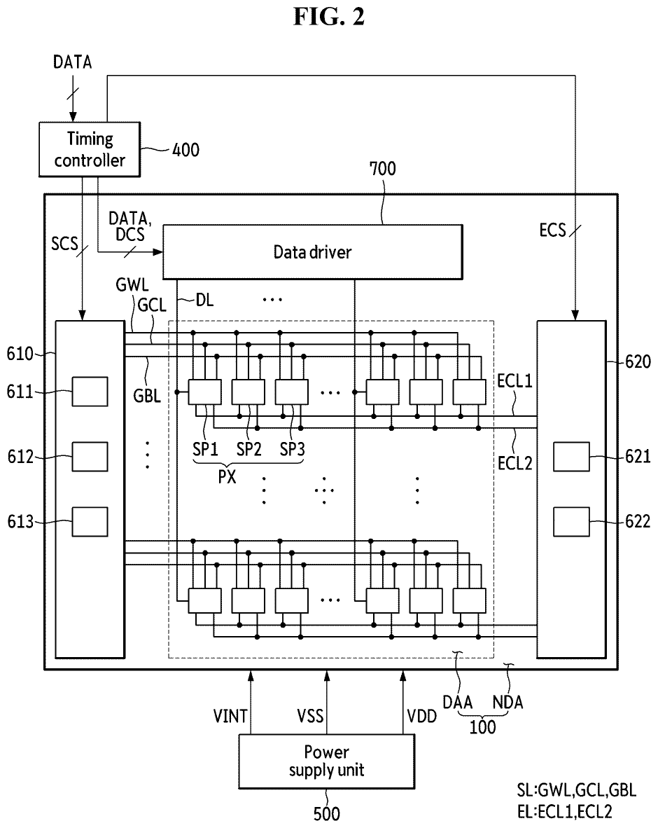

FIG. 1 is an exploded perspective view illustrating a display device according to one or more embodiments. FIG. 2 is a block diagram illustrating the display device according to one or more embodiments.

Referring to FIGS. 1 and 2, a display device 10 according to one or more embodiments is a device that displays a moving image or a still image. The display device 10 according to one or more embodiments may be applied to portable electronic devices, such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according to one or more embodiments may be applied as a display unit of televisions, laptop computers, monitors, billboards, or the Internet of Things (IOTs). Alternatively, the display device 10 according to one or more embodiments may be applied to smart watches, watch phones, or head-mounted displays (HMDs) for implementing virtual reality and augmented reality.

The display device 10 according to one or more embodiments includes a display panel 100, a heat dissipation layer 200, a circuit board 300, a timing control circuit 400, and a power supply circuit 500.

The display panel 100 may have a shape that is similar to a rectangular shape in plan view. For example, the display panel 100 may have a shape similar to a rectangular shape, in plan view, having short sides in a first direction DR1, and long sides in a second direction DR2 crossing the first direction DR1. In the display panel 100, a corner where the short side in the first direction DR1 and the long side in the second direction DR2 meet may be rounded with a curvature (e.g., predetermined curvature) or right-angled. The shape of the display panel 100 in plan view is not limited to the rectangular shape, and may be a shape similar to other polygonal shapes, a circular shape, or an elliptical shape. A shape of the display device 10 in plan view may follow the shape of the display panel 100 in plan view, but the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA for displaying an image, and a non-display area NDA not displaying an image, as shown in FIG. 2.

The plurality of pixels PX may be located in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

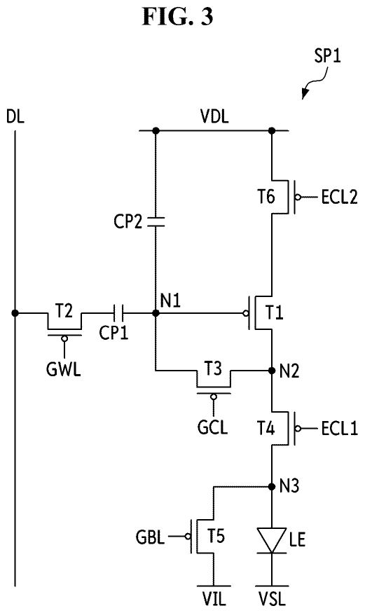

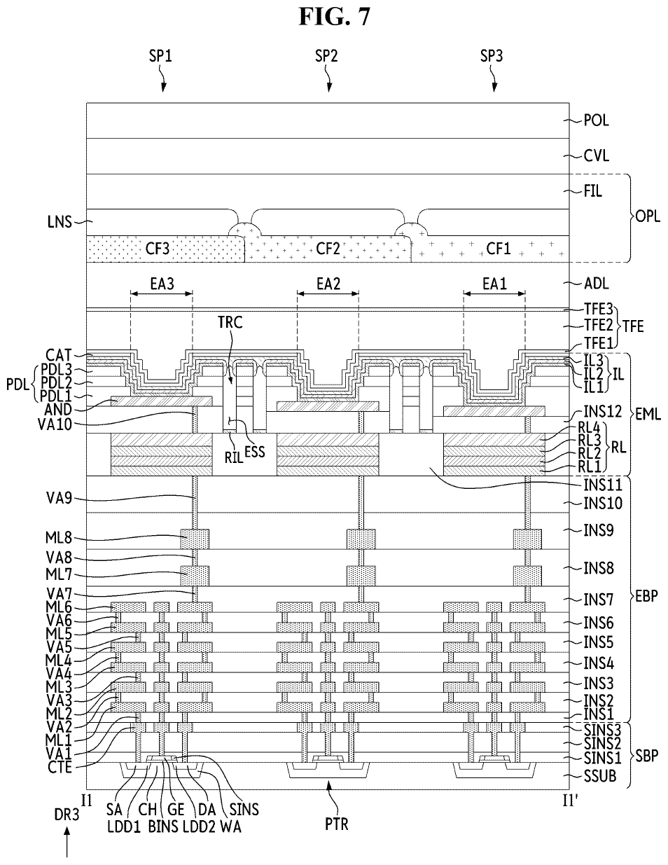

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process, and may be located on a semiconductor substrate SSUB (see FIG. 7). For example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and may emit light from the light-emitting element according to the data voltage.

The scan driver 610, the emission driver 620, and the data driver 700 may be located in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from the timing control circuit 400. The write scan signal output unit 611 may generate write scan signals according to the scan-timing control signal SCS of the timing control circuit 400, and may output them sequentially to the write scan lines GWL. The control scan signal output unit 612 may generate control scan signals in response to the scan-timing control signal SCS, and may sequentially output them to the control scan lines GCL. The bias scan signal output unit 613 may generate bias scan signals according to the scan-timing control signal SCS, and may output them sequentially to the bias scan lines GBL.

The emission driver 620 includes a first emission control driver 621 and a second emission control driver 622. Each of the first emission control driver 621 and the second emission control driver 622 may receive an emission-timing control signal ECS from the timing control circuit 400. The first emission control driver 621 may generate first emission control signals according to the emission-timing control signal ECS and sequentially output them to the first emission control lines ECL1. The second emission control driver 622 may generate second emission control signals according to the emission-timing control signal ECS and sequentially output them to the second emission control lines ECL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS, but the present disclosure is not limited thereto.

The data driver 700 may receive digital video data DATA and a data-timing control signal DCS from the timing control circuit 400. The data driver 700 converts the digital video data DATA into analog data voltages according to the data-timing control signal DCS, and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

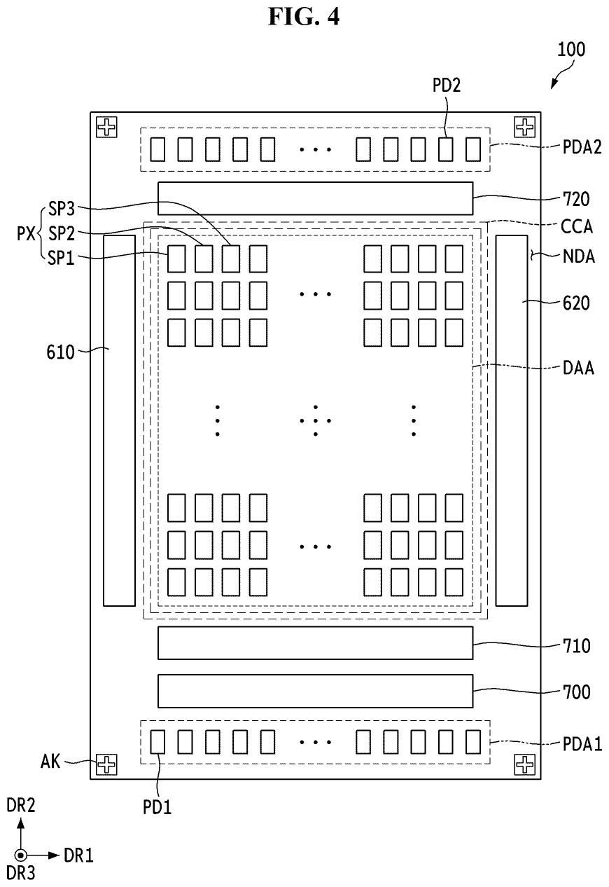

The circuit board 300 may be electrically connected to a plurality of first pads PD1 (see FIG. 4) of a first pad portion PDA1 (see FIG. 4) of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan-timing control signal SCS, the emission-timing control signal ECS, and the data-timing control signal DCS for controlling the display panel 100 in response to the timing signals. The timing control circuit 400 may output the scan-timing control signal SCS to the scan driver 610, and output the emission-timing control signal ECS to the emission driver 620. The timing control circuit 400 may output the digital video data and the data-timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT, and may supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC), and may be attached to one surface of the circuit board 300. In this case, the scan-timing control signal SCS, the emission-timing control signal ECS, the digital video data DATA, and the data-timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similar to the scan driver 610, the emission driver 620, and the data driver 700. In this case, the timing control circuit 400 may include a plurality of timing transistors, and the power supply circuit 500 may include a plurality of power transistors. The plurality of timing transistors and the plurality of power transistors may be formed by a semiconductor process, and may be formed on a semiconductor substrate SSUB (see FIG. 7). For example, the plurality of timing transistors and the plurality of power transistors may be formed as CMOSs, but the present disclosure is not limited thereto. Each of the timing control circuit 400 and the power supply circuit 500 may be located between the data driver 700 and the first pad portion PDA1 (see FIG. 4).

FIG. 3 is an equivalent circuit diagram of a first sub-pixel according to one or more embodiments.

Referring to FIG. 3, a first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light-emitting element LE, a first capacitor CP1, and a second capacitor CP2.

The light-emitting element LE emits light in response to a driving current flowing through the channel of a first transistor T1. The emission amount of the light-emitting element LE may be proportional to the driving current. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but the present disclosure is not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode.

A fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE.

A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE.

A sixth transistor T6 may be located between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be located on the first side of the display area DAA, and the emission driver 620 may be located on the second side of the display area DAA. For example, the scan driver 610 may be located on one side of the display area DAA in the first direction DR1, and the emission driver 620 may be located on the other side of the display area DAA in the first direction DR1. However, the present disclosure is not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on the third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be located on the fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to P data lines DL (P being a positive integer of 2 or more), and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

A cathode connection part CCA may be an area where a second electrode CAT (see FIG. 7) of a display element layer EML (see FIG. 7) is connected to the first driving voltage line VSL of the non-display area NDA. The cathode connection part CCA may be located outside at least one side of the display area DAA. For example, the cathode connection part CCA may be located outside at least one side of the display area DAA. Alternatively, the cathode connection part CCA may be located to surround the display area DAA as shown in FIG. 4 to reduce or minimize deviations of the first driving voltage VSS caused by voltage drop (IR drop) or voltage rise (IR rising) of the second electrode CAT in the display area DAA.

As illustrated in FIG. 4, a plurality of align keys AK may be located at the edge of the display panel 100. The align keys AK, for example, may be used for aligning between the first pad PD1 and the circuit board 300 or aligning between the second pad PD2 and a circuit board for inspection.

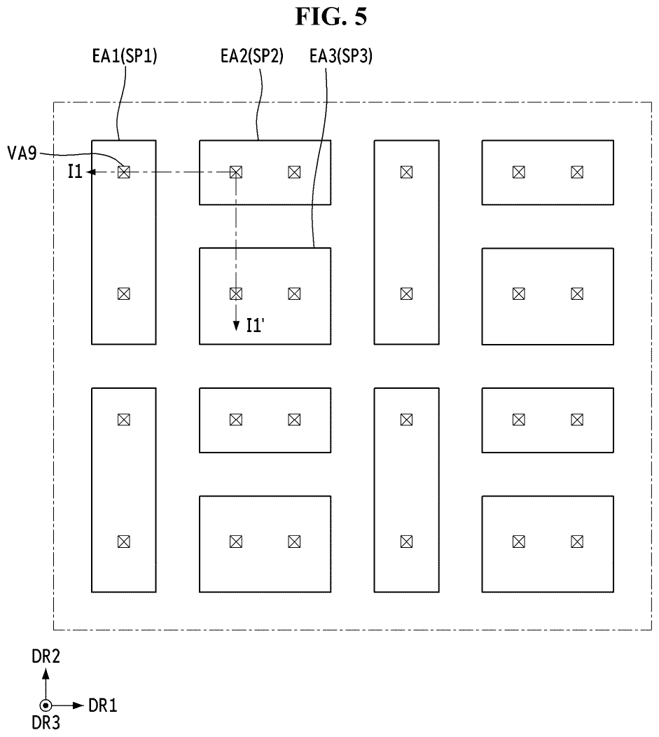

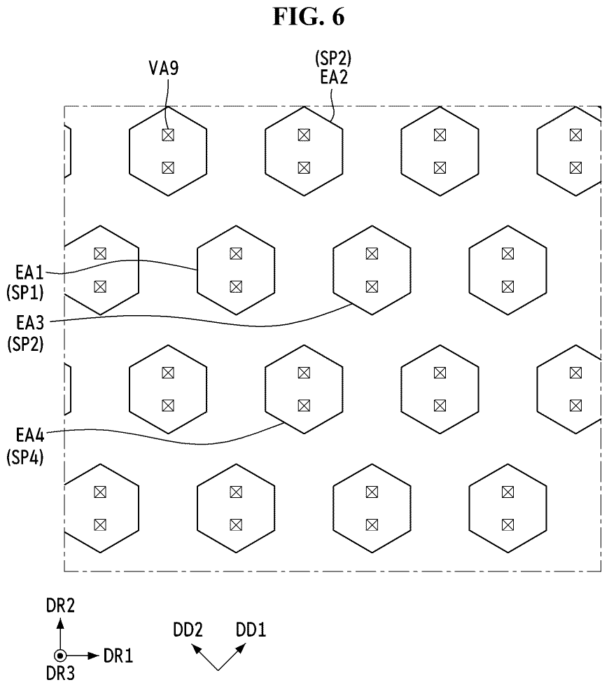

FIG. 5 is a layout diagram illustrating the display area of FIG. 4. FIG. 6 is a layout diagram illustrating the display area of FIG. 4 according to one or more other embodiments.

Referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in plan view, a quadrilateral or hexagonal shape as shown in FIGS. 5 and 6, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different from each other.

Alternatively, as shown in FIG. 6, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in, or aligned in, the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction that is substantially perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to approximately 460 nm, the green wavelength band may be a wavelength band of light whose main peak wavelength is in the range of approximately 480 nm to approximately 560 nm, and the red wavelength band may be a wavelength band of light whose main peak wavelength is in the range of approximately 600 nm to approximately 750 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the present disclosure is not limited thereto.

The emission areas of the plurality of pixels PX may be located in a stripe structure where the emission areas are arranged in the first direction DR1, in a PenTile®/PENTILE™ structure (PenTile® and PENTILE™ being registered trademarks of Samsung Display Co., Ltd., Republic of Korea), where the emission areas EA1, EA2, EA3, and EA4 are arranged in a rhombus shape as shown in FIG. 6, or in a hexagonal structure, where the emission areas are arranged in a hexagonal shape.

FIG. 7 is a cross-sectional view illustrating a display panel taken along the line I1-I1′ of FIG. 5.

Referring to FIG. 7, the display panel 100 includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB (as used herein, “located on” may mean “above”). The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating layer BINS may be located between a gate electrode GE and the well region WA. A side insulating layer SINS may be located on the side surface of the gate electrode GE. The side insulating layer SINS may be located on the lower insulating layer BINS.

Each of the source region SA and the drain region DA may be a region doped with the first type impurity. The gate electrode GE of the pixel transistor PTR may overlap the well region WA in the third direction DR3, which is a thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2, and thus, the length of the channel region CH of each of the pixel transistors PTR may increase.

A first semiconductor insulating layer SINS1 may be located on the semiconductor substrate SSUB. A second semiconductor insulating layer SINS2 may be located on the first semiconductor insulating layer SINS1.

The plurality of contact terminals CTE may be located on the second semiconductor insulating layer SINS2. Each of the plurality of contact terminals CTE may be connected to any one of the gate electrode GE, the source region SA, or the drain region DA of each of the pixel transistors PTR through a hole penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating layer SINS3 may be located on a side surface of each of the plurality of contact terminals CTE. The top surface of each of the plurality of contact terminals CTE may be exposed without being covered by the third semiconductor insulating layer SINS3.

Each of the first semiconductor insulating layer SINS1, the second semiconductor insulating layer SINS2, and the third semiconductor insulating layer SINS3 may formed of silicon carbonitride (SiCN) or a silicon oxide (SiOx)-based inorganic film, but the present disclosure is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS10.

The first to eighth insulating layers INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

For example, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may be formed of substantially the same material. First to eighth insulating layers INS1 to INS8 may be formed of a silicon oxide (SiOx)-based inorganic film, but the present disclosure is not limited thereto.

A ninth insulating layer INS9 may be located on the eighth insulating layer INS8 and the eighth conductive layer ML8. The ninth insulating layer INS9 may be formed of a silicon oxide (SiOx)-based inorganic film, but the present disclosure is not limited thereto.

Each of the ninth vias VA9 may penetrate the tenth insulating layer INS10 and the ninth insulating layer INS9, and may be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

The display element layer EML may be located on the light-emitting element backplane EBP. The display element layer EML may include eleventh and twelfth insulating layers INS11 and INS12, a reflective electrode RL, first electrodes AND, a light-emitting stack IL, a second electrode CAT, a pixel-defining layer PDL, and a plurality of trenches TRC.

The reflective electrode RL may be located on the tenth insulating layer INS10. The reflective electrode RL may include at least one reflective electrode RL1, RL2, RL3, and RL4. For example, the reflective electrode RL may include first to fourth reflective electrodes RL1, RL2, RL3, and RL4 as illustrated in FIG. 7.

The first reflective electrodes RL1 may be located on the tenth insulating layer INS10, and may be connected to the ninth via VA9. Each of the second reflective electrodes RL2 may be located on the corresponding first reflective electrode RL1. Each of the third reflective electrodes RL3 may be located on the corresponding second reflective electrode RL2. Each of the fourth reflective electrodes RL4 may be located on the corresponding third reflective electrode RL3.

Because the second reflective electrodes RL2 are electrodes substantially reflecting light from the light-emitting elements LE, a thickness of the second reflective electrode RL2 may be greater than a thickness of the first reflective electrode RL1, a thickness of the third reflective electrode RL3, and a thickness of the fourth reflective electrode RL4.

Each of the first reflective electrodes RL1 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the first reflective electrodes RL1 may include titanium nitride (TiN), each of the second reflective electrodes RL2 may include aluminum (Al), each of the third reflective electrodes RL3 may include titanium nitride (TiN), and each of the fourth reflective electrodes RL4 may include titanium (Ti).

The eleventh insulating layer INS11 may be located on the tenth insulating layer INS10. The eleventh insulating layer INS11 may be located between the neighboring reflective electrodes RL. The eleventh insulating layer INS11 may be a film for planarizing steps due to the reflective electrodes RL. The twelfth insulating layer INS12 may be located on the eleventh insulating layer INS11 and the reflective electrode RL.

The eleventh insulating layer INS11 and the twelfth insulating layer INS12 may be formed as a silicon oxide (SiOₓ)-based inorganic film, but the present disclosure is not limited thereto.

The twelfth insulating layer INS12 may be an optical auxiliary layer for adjusting a resonance distance of light emitted from the light-emitting stack IL in at least one sub-pixel among the first sub-pixel SP1, the second sub-pixel SP2, and the third sub-pixel SP3. The thickness of twelfth insulating layer INS12 may be different in the first sub-pixel SP1, the second sub-pixel SP2, and the third sub-pixel SP3. That is, to adjust a distance from the reflective electrode RL to the second electrode CAT according to a main wavelength of light emitted from each of the first sub-pixel SP1, the second sub-pixel SP2, and the third sub-pixel SP3, the thickness of the twelfth insulating layer INS12 may be set (e.g., differently set) in each of the first sub-pixel SP1, the second sub-pixel SP2, and the third sub-pixel SP3.

For example, as illustrated in FIG. 7, the thickness of the twelfth insulating layer INS12 in the first sub-pixel SP1 may be greater than the thickness of the twelfth insulating layer INS12 in the second sub-pixel SP2. The thickness of the twelfth insulating layer INS12 in the second sub-pixel SP2 may be greater than the thickness of the twelfth insulating layer INS12 in the third sub-pixel SP3. In this case, the distance between the first electrode AND the reflective electrode RL in the first sub-pixel SP1 may be greater than the distance between the first electrode AND and the reflective electrode RL in the second sub-pixel SP2. In addition, the distance between the first electrode AND and the reflective electrode RL in the second sub-pixel SP2 may be greater than the distance between the first electrode AND and the reflective electrode RL in the third sub-pixel SP3.

Each of the tenth vias VA10 may penetrate the twelfth insulating layer INS12, and may be connected to the exposed fourth reflective electrodes RL4. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be located on the twelfth insulating layer INS12, and may be connected to the tenth via VA10. The first electrode AND of each of the light-emitting elements LE may be connected to the drain region DA or the source region SA of the pixel transistor PTR through the tenth via VA10, the reflective electrode RL, the first to ninth vias VA1 to VA9, the first to eighth conductive layers ML1 to ML8, and the contact terminal CTE. The first electrode AND of each of the light-emitting elements LE may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, the first electrode AND of each of the light-emitting elements LE may be made of titanium nitride (TiN).

The pixel-defining layer PDL may be located on a partial area of the first electrode AND of each of the light-emitting elements LE. The pixel-defining layer PDL may cover an edge of the first electrode AND of each of the light-emitting elements LE. The pixel-defining layer PDL may partition the first emission areas EA1, the second emission areas EA2, and the third emission areas EA3. Each of the first emission area EA1, the second emission area EA2, and the third emission area EA3 may be an area where the light-emitting element LE including a first electrode AND, a light-emitting stack IL, and a second electrode CAT is located.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining layer PDL may include first to third pixel-defining layers PDL1, PDL2, and PDL3. The first pixel-defining layer PDL1 may be located on the edge of the first electrode AND of each of the light-emitting elements LE, the second pixel-defining layer PDL2 may be located on the first pixel-defining layer PDL1, and the third pixel-defining layer PDL3 may be located on the second pixel-defining layer PDL2. The first pixel-defining layer PDL1, the second pixel-defining layer PDL2, and the third pixel-defining layer PDL3 may be formed of a silicon oxide (SiOₓ)-based inorganic film. Alternatively, the first pixel-defining layer PDL1 and the third pixel-defining layer PDL3 may be formed of a silicon nitride (SiNx)-based inorganic layer, while the second pixel-defining layer PDL2 may be formed of a silicon oxide (SiOₓ)-based inorganic film. The first pixel-defining layer PDL1, the second pixel-defining layer PDL2, and the third pixel-defining layer PDL3 may each have a thickness of about 500 Å.

To reduce or prevent the likelihood of the first encapsulation inorganic film TFE1 being cut off due to the step coverage, the first pixel-defining layer PDL1, the second pixel-defining layer PDL2, and the third pixel-defining layer PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate through the first pixel-defining layer PDL1, the second pixel-defining layer PDL2, and the third pixel-defining layer PDL3. In each of the plurality of trenches TRC, the eleventh insulating film INS11 may have a shape in which at least a portion thereof is trenched.

At least one trench TRC may be located between the neighboring sub-pixels SP1, SP2, and SP3. Although FIG. 7 illustrates that two trenches TRC are located between adjacent sub-pixels SP1, SP2, and SP3, the present disclosure is not limited thereto.

The light-emitting stack IL may include a plurality of stack layers IL1, IL2, and IL3. It has been illustrated in FIG. 7 that the light-emitting stack IL has a three-tandem structure including a first stack layer IL1, a second stack layer IL2, and a third stack layer IL3, but the present disclosure is not limited thereto. For example, the light-emitting stack IL may have a two-tandem structure including two stack layers.

In the three-tandem structure, the light-emitting stack IL may have a tandem structure including a plurality of stack layers IL1, IL2, and IL3 for emitting different light. For example, the light-emitting stack IL may include a first stack layer IL1 for emitting light of a first color, a second stack layer IL2 for emitting light of a second color, and a third stack layer IL3 for emitting light of a third color. The first stack layer IL1, the second stack layer IL2, and the third stack layer IL3 may be sequentially stacked.

The first stack layer IL1 may have a structure in which a first hole-transporting layer, a first light-emitting layer for emitting the light of the first color, and a first electron-transporting layer are sequentially stacked. The second stack layer IL2 may have a structure in which a second hole-transporting layer, a second light-emitting layer for emitting the light of the second color, and a second electron-transporting layer are sequentially stacked. The third stack layer IL3 may have a structure in which a third hole-transporting layer, a third organic light-emitting layer for emitting the light of the third color, and a third electron-transporting layer are sequentially stacked.

A first charge generation layer for supplying charges to the second stack layer IL2 and for supplying electrons to the first stack layer IL1 may be located between the first stack layer IL1 and the second stack layer IL2. The first charge generation layer may include an N-type charge generation layer for supplying electrons to the first stack layer IL1 and a P-type charge generation layer for supplying holes to the second stack layer IL2. The N-type charge generation layer may include a dopant of a metal material.

A second charge generation layer for supplying charges to the third stack layer IL3 and for supplying electrons to the second stack layer IL2 may be located between the second stack layer IL2 and the third stack layer IL3. The second charge generation layer may include an N-type charge generation layer for supplying electrons to the second stack layer IL2 and a P-type charge generation layer for supplying holes to the third stack layer IL3.

The first stack layer IL1 may be located on the first electrodes AND and the pixel-defining layer PDL, and a residual film RIL located on the bottom surface of the trench TRC in each of the trenches TRC may be the same material as the first stack layer IL1. Due to the trenches TRC, the first stack layer IL1 may be disconnected between the sub-pixels SP1, SP2, and SP3 neighboring to each other. The second stack layer IL2 may be located on the first stack layer IL1. Due to the trenches TRC, the second stack layer IL2 may be disconnected between the sub-pixels SP1, SP2, and SP3 neighboring to each other. A cavity ESS or an empty space may be located between the residual film RIL and the second stack layer IL2. The third stack layer IL3 may be located on the second stack layer IL2. The third stack layer IL3 may not be disconnected by the trenches TRC, and may be located to cover the second stack layer IL2 in each of the trenches TRC.

In the three-tandem structure, each of the plurality of trenches TRC may be a structure for disconnecting the first to third hole-transporting layers of each of the first to third stack layers IL1 to IL3, the first charge generation layer, and the second charge generation layer of the display element layer EML between sub-pixels SP1, SP2, and SP3 neighboring to each other. In addition, in the two-tandem structure, each of the plurality of trenches TRC may be a structure for disconnecting a charge generation layer located between a lower stack layer and an upper stack layer and the lower stack layer.

To stably disconnect the first and second stack layers IL1 and IL2 of the display element layer EML between the sub-pixels SP1, SP2, and SP3 neighboring to each other, a height of each of the plurality of trenches TRC may be greater than a height of the pixel-defining layer PDL. The height of each of the plurality of trenches TRC refers to a length of each of the plurality of trenches TRC in the third direction DR3. The height of the pixel-defining layer PDL refers to a length of the pixel-defining layer PDL in the third direction DR3. To disconnect the hole-transporting layers and the charge generation layers of the light-emitting stack IL of the display element layer EML between the sub-pixels SP1, SP2, and SP3 neighboring to each other, other structures may exist instead of the trenches TRC. For example, instead of the trenches TRC, partition walls having a reverse tapered shape may be located on the pixel-defining layer PDL.

It has been illustrated in FIG. 7 that the light-emitting stack IL is entirely located in the first emission area EA1, the second emission area EA2, and the third emission area EA3, but the present disclosure is not limited thereto. For example, instead of the light-emitting stack IL, a first light-emitting layer may be located in the first emission area EA1, and may be omitted from the second emission area EA2 and the third emission area EA3. In addition, a second light-emitting layer may be located in the second emission area EA2, and may be omitted form the first emission area EA1 and the third emission area EA3. Moreover, a third light-emitting layer may be located in the third emission area EA3, and may be omitted from the first emission area EA1 and the second emission area EA2. In this case, first to third color filters CF1, CF2, and CF3 of the optical layer OPL may be omitted.

The second electrode CAT may be located on the light-emitting stack IL. The second electrode CAT may be located on the third stack layer IL3 in each of the plurality of trenches TRC. The second electrode CAT may be made of a transparent conductive material (TCO), such as indium tin oxide (ITO) or indium zinc oxide (IZO) capable of transmitting light therethrough or a semi-transmissive conductive material, such as magnesium (Mg), silver (Ag), or an alloy of magnesium (Mg) and silver (Ag). When the second electrode CAT is made of the semi-transmissive conductive material, light emission efficiency of each of the first to third sub-pixels SP1, SP2, and SP3 may be increased by a micro cavity.

The encapsulation layer TFE may be located on the display element layer EML. The encapsulation layer TFE may include at least one inorganic film TFE1 and TFE3 to reduce or prevent oxygen or moisture from permeating into the display element layer EML. For example, a first encapsulation inorganic film TFE1 may be located on the second electrode CAT, and a second encapsulation inorganic film TFE3 may be located on the first encapsulation inorganic film TFE1. Each of the first encapsulation inorganic film TFE1 and the second encapsulation inorganic film TFE3 may be formed as a multilayer in which one or more inorganic films selected from silicon nitride (SiNx), silicon oxy nitride (SiON), silicon oxide (SiOx), titanium oxide (TiOx), and/or aluminum oxide (AlOx) are alternately stacked.

In addition, the encapsulation layer TFE may include at least one organic film TFE2 to protect the display element layer EML from foreign substances, such as dust. For example, the encapsulation organic film TFE2 may be located between the first encapsulation inorganic film TFE1 and the second encapsulation inorganic film TFE3. The encapsulation organic film TFE2 may be a monomer. Alternatively, the encapsulation organic film TFE2 may be an organic film, such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member, such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first sub-pixel SP1. The first color filter CF1 may transmit light of the first color (e.g., light of a blue wavelength band). The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color (e.g., light of a green wavelength band). The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color (e.g., light of a red wavelength band). The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

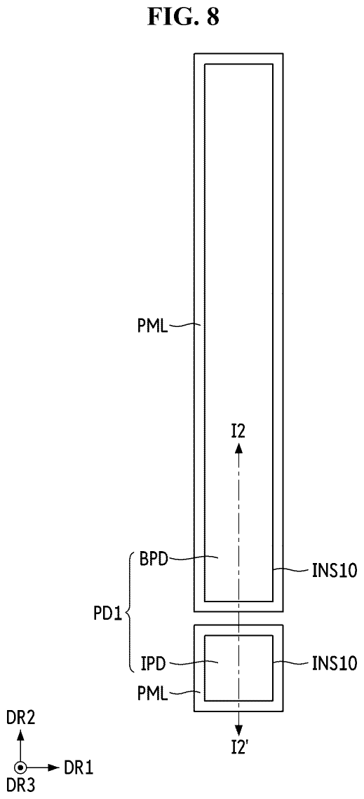

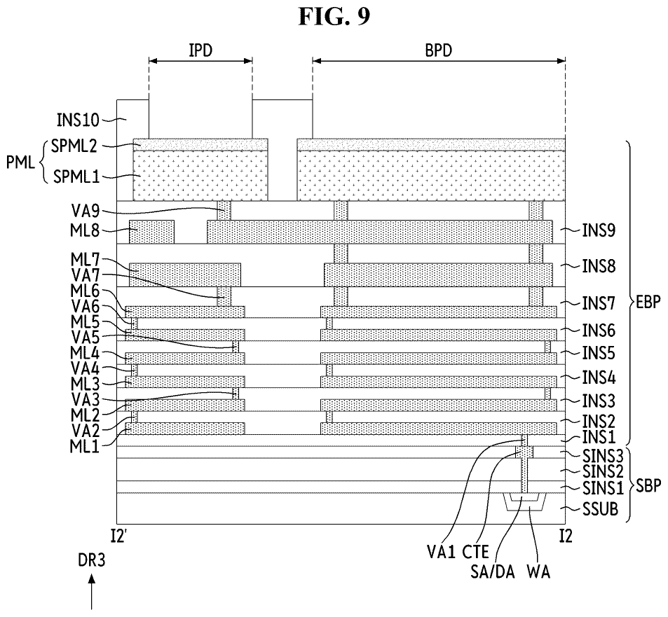

FIG. 8 is a layout diagram illustrating a first pad of a first pad portion of FIG. 4. FIG. 9 is a cross-sectional view illustrating a display panel taken along the line I2-I2′ of FIG. 8.

Referring to FIGS. 8 and 9, each of the first pads PD1 includes a first sub-pad BPD and a second sub-pad IPD. Both of the first sub-pad BPD and the second sub-pad IPD may be electrically connected to a pad or a bump of the circuit board 300 through a conductive adhesive member. In addition, the second sub-pad IPD may be a pad connected to a jig or a probe pin or a circuit board for inspection in an inspection process.

An area of the first sub-pad BPD may be larger than an area of the second sub-pad IPD. The width of the first sub-pad BPD in the first direction DR1 may be substantially the same as the width of the second sub-pad IPD in the first direction DR1. The length of the first sub-pad BPD in the second direction DR2 may be longer than the length of the second sub-pad IPD in the second direction DR2.

Each of the first sub-pad BPD and the second sub-pad IPD may include a pad conductive layer PML. The pad conductive layer PML may include a first sub-pad conductive layer SPML1 and a second sub-pad conductive layer SPML2. The first sub-pad conductive layer SPML1 may be made of any one of copper (Cu), aluminum (Al), tungsten (W), molybdenum (Mo), chromium (Cr), gold (Au), titanium (Ti), nickel (Ni), or neodymium (Nd), or alloys thereof. The second sub-pad conductive layer SPML2 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, the first sub-pad conductive layer SPML1 may be made of aluminum (Al).

The thickness of the first sub-pad conductive layer SPML1 may be greater than the thickness of the reflective electrode RL. For example, the first sub-pad conductive layer SPML1 may have a thickness of approximately 10,000 Å or more (e.g., a thickness of 12,000 Å or more). In addition, the second sub-pad conductive layer SPML2 may be made of titanium nitride (TiN), and may have a thickness of approximately 1,000 Å or less (e.g., a thickness of approximately 600 Å). Because the first sub-pad conductive layer SPML1 is formed to have a thickness of approximately 10,000 Å or more, even when a pressure is applied to a jig or a probe pin in the pad conductive layer PML in an inspection process, damage to the pad conductive layer PML may be reduced or prevented.

The pad conductive layer PML of the first sub-pad BPD and the pad conductive layer PML of the second sub-pad IPD may be located apart from each other, but may be connected the eighth conductive layer ML8 through the ninth via VA9 penetrating the ninth insulating layer INS9. For example, the first sub-pad conductive layer SPML1 of the first sub-pad BPD and the first sub-pad conductive layer SPML1 of the second sub-pad IPD may be connected to the eighth conductive layer ML8 through the ninth via VA9 penetrating the ninth insulating layer INS9. Accordingly, the pad conductive layer PML of the first sub-pad BPD and the conductive layer PML of the second sub-pad IPD may have substantially the same potential.

As illustrated in FIGS. 8 and 9, as the pad conductive layer PML of the first sub-pad BPD and the pad conductive layer PML of the second sub-pad IPD are separated or distinguished from each other, even if the pad conductive layer PML of the second sub-pad IPD is damaged or broken by a jig or a probe pin in an inspection process, the pad conductive layer PML of the first sub-pad BPD may not be damaged or broken. That is, by physically separating the first sub-pad connected to the circuit board 300 and the second sub-pad IPD used in an inspection process, the pad conductive layer PML of the first sub-pad BPD may be connected stably to the circuit board 300 even if the pad conductive layer PML of the second sub-pad IPD is damaged.

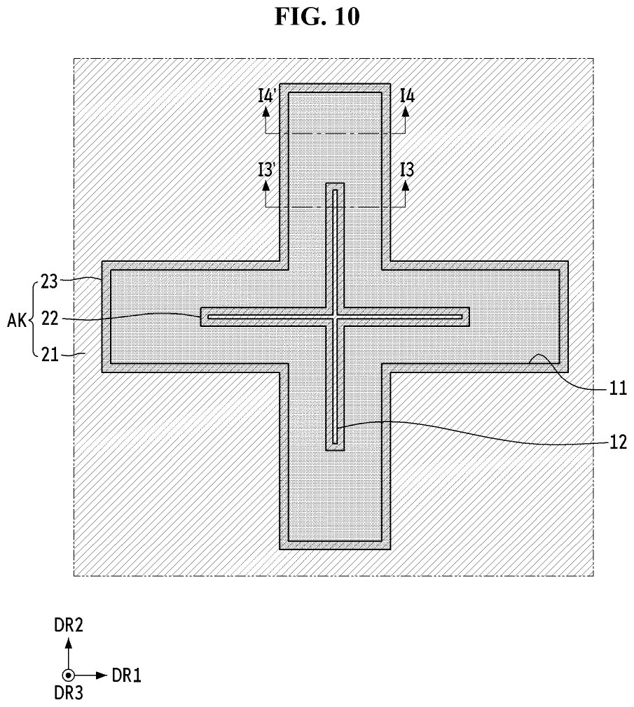

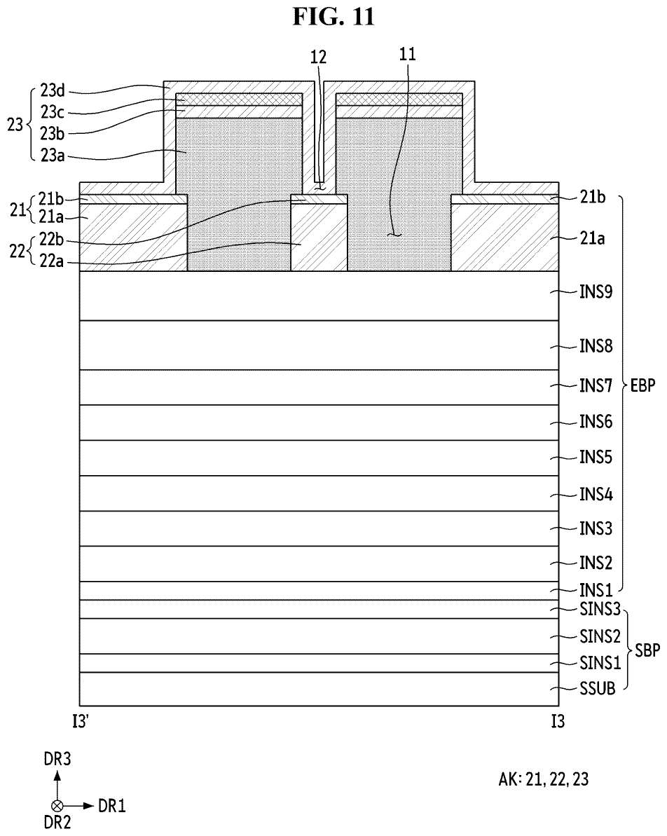

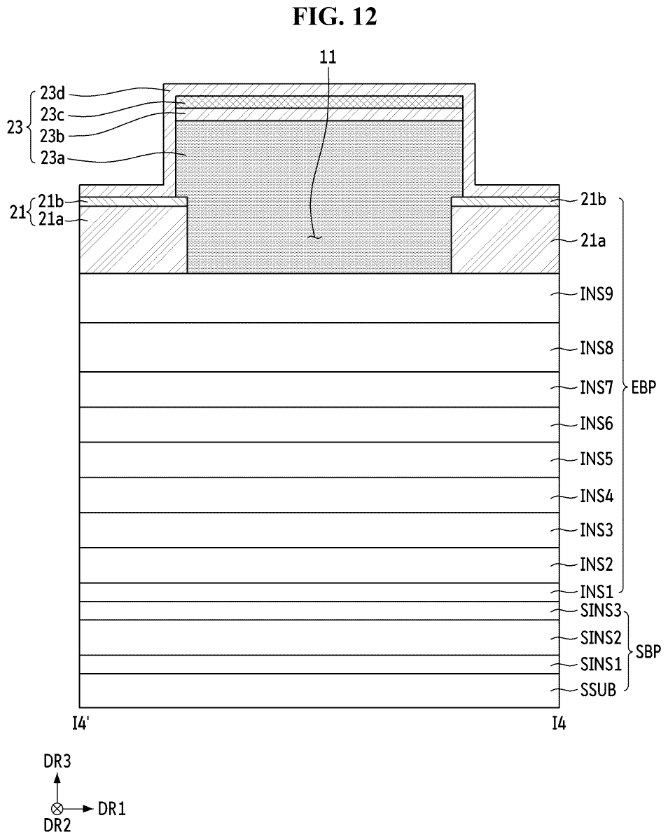

FIG. 10 is a plan view of an align key AK of FIG. 4. FIG. 11 is a cross-sectional view illustrating a display panel taken along the line I3-I3′ of FIG. 10. FIG. 12 is a cross-sectional view illustrating a display panel taken along the line I4-I4′ of FIG. 10.

As illustrated in FIGS. 10 and 11, the align key AK may include an outer pattern layer 21, an inner pattern layer 22, and a dummy layer 23. As illustrated in FIGS. 11 and 12, the align key AK may be located on or above the ninth insulating layer INS9. The align key AK may overlap the first to third semiconductor insulating layers SINS1 to SINS3 of the semiconductor backplane SBP and the first to ninth insulating layers INS1 to INS9 of the light-emitting element backplane EBP above the substrate (e.g., semiconductor substrate SSUB) in the third direction DR3. At this time, the align key AK may not overlap other metal layers in the third direction DR3.

In plan view illustrated in FIG. 10, the outer pattern layer 21 may have a quadrilateral shape. However, the shape of the outer pattern layer 21 is not limited thereto, and may be changed in various shapes. The outer pattern layer 21 may have a through hole 11. For example, the through hole 11 may be defined by the outer pattern layer 21. The through hole 11 may penetrate the outer pattern layer 21 in the third direction DR3. In plan view, the through hole 11 may have a cross shape. However, the shape of the through hole 11 is not limited thereto, and may be changed in various shapes. The outer pattern layer 21 may include a first sub-outer pattern layer 21a and a second sub-outer pattern layer 21b located on different layers.

The first sub-outer pattern layer 21a of the outer pattern layer 21 may be located on the ninth insulating layer INS9, and the second sub-outer pattern layer 21b of the outer pattern layer 21 may be located on the first sub-outer pattern layer 21a. The first sub-outer pattern layer 21a and the second sub-outer pattern layer 21b may overlap each other in the third direction DR3, and may be in contact with each other.

The outer pattern layer 21 may be made of the same material as the first pad PD1 described above. For example, the outer pattern layer 21 may be made of the same material as the pad conductive layer PML of the first pad PD1. For example, the first sub-outer pattern layer 21a of the outer pattern layer 21 may be made of the same material as the first sub-pad conductive layer SPML1 described above, and the second sub-outer pattern layer 21b of the outer pattern layer 21 may be made of the same material as the second sub-pad conductive layer SPML2. The outer pattern layer 21 and the pad conductive layer PML may be formed together by the same process.

The inner pattern layer 22 may be located inside the through hole 11 of the outer pattern layer 21. For example, in plan view, the inner pattern layer 22 may be surrounded by the edge of the outer pattern layer 21 (or the through hole 11 of the outer pattern layer 21). In plan view, the inner pattern layer 22 may have the same shape as the through hole 11. For example, the inner pattern layer 22 may have a cross shape. However, the shape of the inner pattern layer 22 is not limited thereto, and may be changed in various shapes. The inner pattern layer 22 may include a first sub-inner pattern layer 22a and a second sub-inner pattern layer 22b located on different layers.

The first sub-inner pattern layer 22a of the inner pattern layer 22 may be located on the ninth insulating layer INS9 inside the through hole 11, and the second sub-inner pattern layer 22b of the inner pattern layer 22 may be located on the first sub-inner pattern layer 22a. The first sub-inner pattern layer 22a and the second sub-inner pattern layer 22b may overlap each other in the third direction DR3, and may be in contact with each other.

The inner pattern layer 22 may be made of the same material as the outer pattern layer 21. For example, the first sub-inner pattern layer 22a of the inner pattern layer 22 may be made of the same material as the first sub-outer pattern layer 21a described above, and the second sub-inner pattern layer 22b of the inner pattern layer 22 may be made of the same material as the second sub-outer pattern layer 21b described above. The inner pattern layer 22 and the outer pattern layer 21 may be formed together by the same process(es). The thickness of the inner pattern layer 22 in the third direction DR3 and the thickness of the outer pattern layer 21 in the third direction DR3 may be the same.

The dummy layer 23 may be located between the outer pattern layer 21 and the inner pattern layer 22. For example, the dummy layer 23 may be located on the ninth insulating layer INS9 in the through hole 11 of the outer pattern layer 21. A portion of the dummy layer 23 may be located inside the through hole 11. The dummy layer 23 may extend in the third direction DR3 to be located on (e.g., to be partially located on or above) the outer pattern layer 21 and the inner pattern layer 22.

The dummy layer 23 may have a through hole 12 penetrating therethrough. The through hole 12 of the dummy layer 23 may be located on the inner pattern layer 22 to overlap the inner pattern layer 22. The through hole 12 of the dummy layer 23 may have the same shape as the inner pattern layer 22. For example, the through hole 12 of the dummy layer 23 may have a cross shape.

The dummy layer 23 may include a first sub-dummy layer 23a, a second sub-dummy layer 23b, a third sub-dummy layer 23c, and a fourth sub-dummy layer 23d.

The first sub-dummy layer 23a of the dummy layer 23 may be located on the ninth insulating layer INS9 between the through hole 11 and the inner pattern layer 22 (e.g., between the outer pattern layer 21 and the inner pattern layer 22). A portion of the first sub-dummy layer 23a may be located inside the through hole 11. The first sub-dummy layer 23a may extend in the third direction DR3 to be located on the outer pattern layer 21 and the inner pattern layer 22. The first sub-dummy layer 23a, for example, may be made of the same material as the tenth insulating layer INS10. The first sub-dummy layer 23a and the tenth insulating layer INS10 may be made together by the same process.

The second sub-dummy layer 23b of the dummy layer 23 may be located on the first sub-dummy layer 23a. The second sub-dummy layer 23b may overlap the first sub-dummy layer 23a in the third direction DR3, and may be in contact with each other. The second sub-dummy layer 23b may be made of the same material as the first pixel-defining layer PDL1 described above. The second sub-dummy layer 23b and the first pixel-defining layer PDL1 may be formed together by the same process.

The third sub-dummy layer 23c of the dummy layer 23 may be located on the second sub-dummy layer 23b. The third sub-dummy layer 23c may overlap the second sub-dummy layer 23b in the third direction DR3, and may be in contact with each other. The third sub-dummy layer 23c may be made of the same material as the second pixel-defining layer PDL2 described above. The third sub-dummy layer 23c and the second pixel-defining layer PDL2 may be formed together by the same process.

The fourth sub-dummy layer 23d of the dummy layer 23 may be located on the third sub-dummy layer 23c, on the outer pattern layer 21, and on the inner pattern layer 22. The fourth sub-dummy layer 23d may overlap the third sub-dummy layer 23c in the third direction DR3, and may be in contact with each other. In addition, the fourth sub-dummy layer 23d may be located on a side surface of (e.g., on a partial side surface of) the first sub-dummy layer 23a, on a side surface of the second sub-dummy layer 23b, and on a side surface of the third sub-dummy layer 23c. The fourth sub-dummy layer 23d may be made of the same material as the third pixel-defining layer PDL3 described above. The fourth sub-dummy layer 23d and the third pixel-defining layer PDL3 may be formed by the same process. In one or more embodiments, the fourth sub-dummy layer 23d and the third pixel-defining layer PDL3 may be connected to be integrally formed.

The thickness of the first sub-dummy layer 23a in the third direction DR3 may be greater than the thickness of the outer pattern layer 21 in the third direction DR3. In one or more embodiments, the thickness of the first sub-dummy layer 23a in the third direction DR3 may be greater than the thickness of the inner pattern layer 22 in the third direction DR3. In one or more embodiments, the thickness of the first sub-dummy layer 23a in the third direction DR3 may be greater than the thickness of the second sub-dummy layer 23b in the third direction DR3. In one or more embodiments, the thickness of the first sub-dummy layer 23a in the third direction DR3 may be greater than the thickness of the third sub-dummy layer 23c in the third direction DR3. In one or more embodiments, the thickness of the first sub-dummy layer 23a in the third direction DR3 may be greater than the thickness of the fourth sub-dummy layer 23d in the third direction DR3.

For example, the align key AK may be captured or detected by an optical device. At this time, the align key AK may be recognized (or detected) due to the outer pattern layer 21 and the inner pattern layer 22, each of which may be formed of a metal, and due to the dummy layer 23 located between the outer pattern layer 21 and the inner pattern layer 22, which may be formed of a non-metal. For example, the cross-shaped through hole 11 may be clearly recognized (or detected) as a shape of the align key AK due to the difference in reflectance between metal and non-metal in the relevant area. The optical device described above may capture an image of the align key AK at the area of the align key AK. For example, when in process of capturing the align key AK, the align key AK may be located between the optical device and the ninth insulating layer INS9.

In addition, during the manufacturing process of the display device 10, because the outer pattern layer 21 and the inner pattern layer 22 may be covered (or protected) by the fourth sub-dummy layer 23d of the dummy layer 23, damage of the outer pattern layer 21 and the inner pattern layer 22 may be reduced or prevented during the processing process of the display device 10. Accordingly, a likelihood of a visibility error of the align key AK due to the damage of the outer pattern layer 21 or the inner pattern layer 22 may be reduced or prevented.

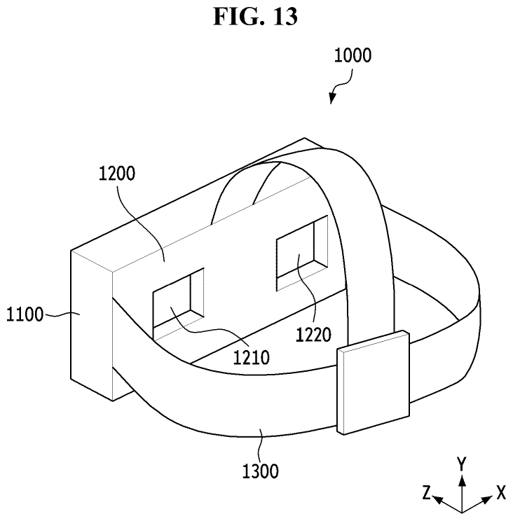

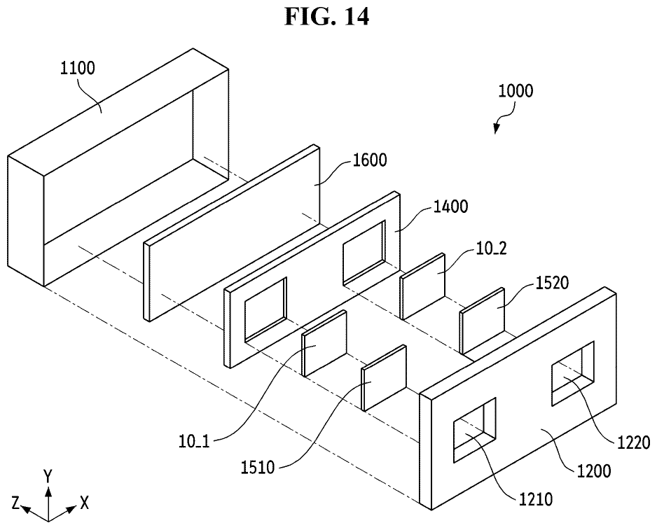

FIG. 13 is a perspective view illustrating a head-mounted display device according to one or more embodiments. FIG. 14 is an exploded perspective view illustrating the head-mounted display device of FIG. 13.

Referring to FIGS. 13 and 14, a head-mounted display 1000 according to one or more embodiments includes a first display device 10_1, a second display device 10_2, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 may be substantially the same as the display device 10 described in conjunction with FIGS. 1 to 12, description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600, and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 13 and 14 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

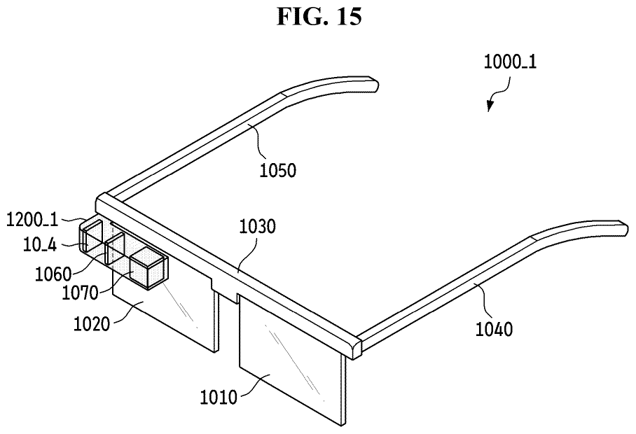

The head-mounted band 1300 serves to secure the display device housing 1100 to the user's head such that the first eyepiece 1210 and the second eyepiece 1220 of the housing cover 1200 remain located on the user's left and right eyes, respectively. When the display device housing 1200_1 is implemented to be lightweight and compact, the head-mounted display 1000 may be provided with an eyeglass frame as shown in FIG. 15 instead of the head-mounted band 1300.

FIG. 15 is a perspective view illustrating a head-mounted display device according to one or more other embodiments.

Referring to FIG. 15, a head-mounted display 1000_1 according to one or more embodiments may be an eyeglasses-type display device in which a display device housing 1200_1 is implemented in a lightweight and compact manner. The head-mounted display 1000_1 according to one or more embodiments may include a display device 10_3, a left eye lens 1010, a right eye lens 1020, a support frame 1030, temples 1040 and 1050, an optical member 1060, an optical-path-changing member 1070, and the display device housing 1200_1.

The display device housing 1200_1 may include the display device 10_4, the optical member 1060, and the optical-path-changing member 1070. An image displayed on the display device 10_4 may be magnified by the optical member 1060, converted in an optical path by the optical-path-changing member 1070, and provided to a user's right eye through the right eye lens 1020. For this reason, a user may view an augmented reality image in which a virtual image displayed on the display device 10_4 through his/her right eye and a real image seen through the right eye lens 1020 are combined with each other.

It has been illustrated in FIG. 15 that the display device housing 1200_1 is located at a right end of the support frame 1030, but the present disclosure is not limited thereto. For example, the display device housing 1200_1 may be located at a left end of the support frame 1030, and in this case, an image of the display device 10_4 may be provided to a user's left eye. Alternatively, the display device housing 1200_1 may be located at both the left and right ends of the support frame 1030, and in this case, the user may view an image displayed on the display device 10_4 through both his/her left and right eyes.

The display device can be applied to various electronic devices. The electronic device according to one or more embodiments includes the display device described above, and may further include modules or devices having additional functions in addition to the display device.

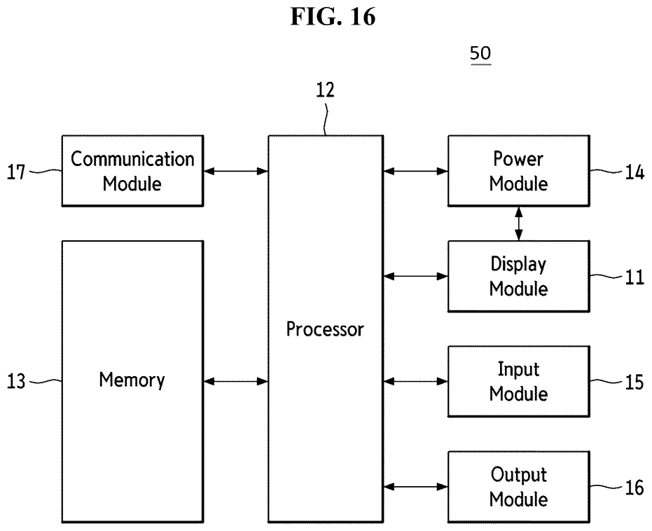

FIG. 16 is a block diagram of an electronic device according to one or more embodiments. Referring to FIG. 16, the electronic device 50 according to one or more embodiments may include a display module, a processor 12, a memory 13, and a power module 14. The electronic device 50 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module, such as a power adapter or a battery device, and a power conversion module that converts the power supplied by the power supply module to generate power required for the operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 50 other than the display device.

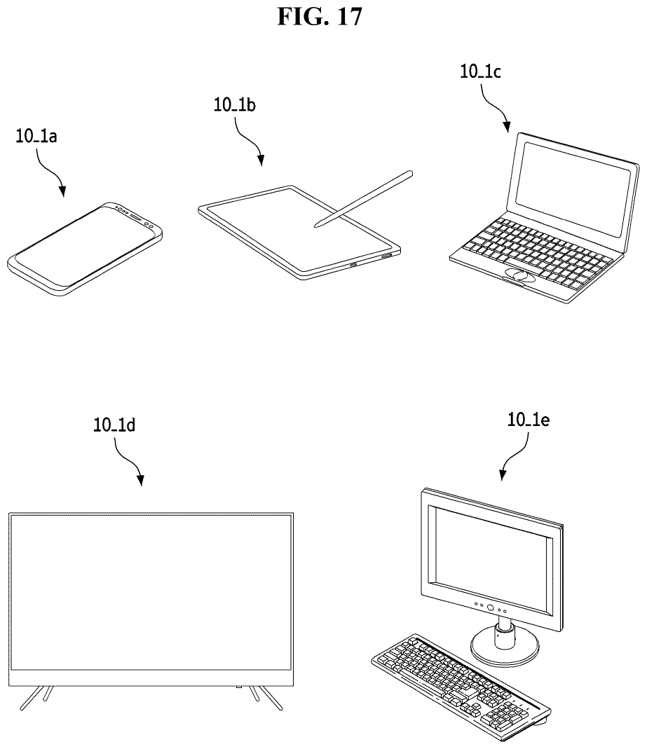

FIGS. 16, 17, and 18 are schematic diagrams of electronic devices according to various embodiments. FIGS. 16 to 18 illustrate examples of various electronic devices to which the display device according to the embodiments is applied.

FIG. 16 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module, such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also may include display modules and input modules similar to smartphones 10_1, and may additionally include communication modules in some cases.

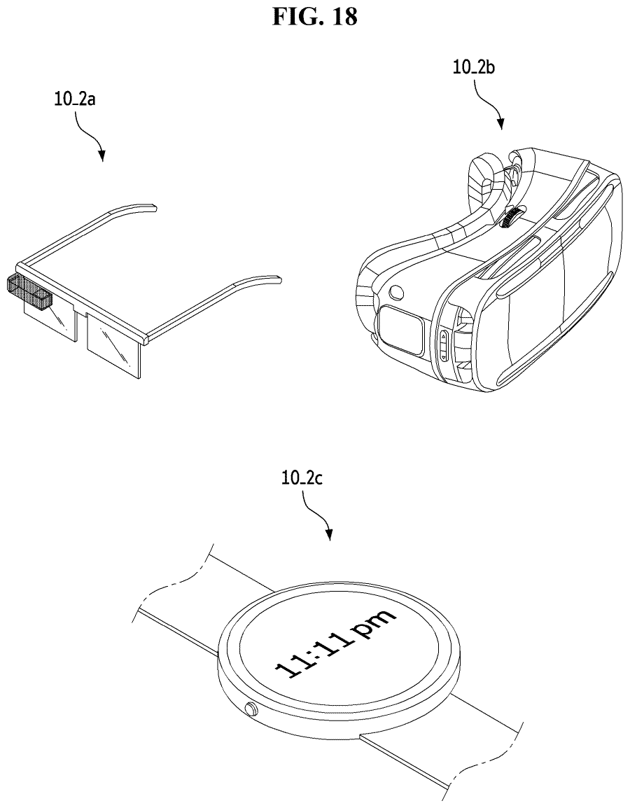

FIG. 18 shows an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module.

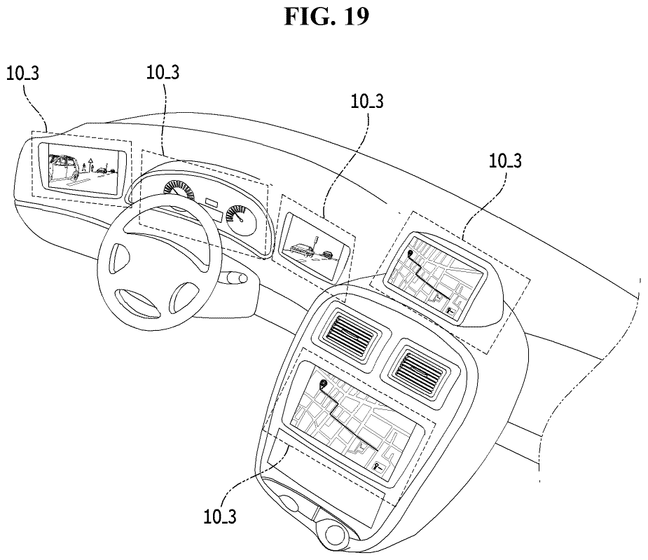

FIG. 19 illustrates a case where an electronic device including a display module is applied to a vehicle. For example, the display device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a substrate;
a first electrode on the substrate;
a pixel-defining layer above the first electrode;
a light-emitting stack above the first electrode and the pixel-defining layer;
a second electrode above the light-emitting stack; and
an align key in a non-display area of the substrate, and comprising:
an outer pattern layer above the substrate;
an inner pattern layer inside a through hole of the outer pattern layer; and
a dummy layer between the outer pattern layer and the inner pattern layer.

2. The display device of claim 1, wherein the outer pattern layer and the inner pattern layer comprise metal, and
wherein the dummy layer comprises a non-metal.

3. The display device of claim 1, wherein the inner pattern layer is surrounded by the outer pattern layer in plan view.

4. The display device of claim 1, wherein the outer pattern layer comprises:
a first sub-outer pattern layer; and
a second sub-outer pattern layer above the first sub-outer pattern layer.

5. The display device of claim 1, wherein the inner pattern layer comprises:
a first sub-inner pattern layer; and
a second sub-inner pattern layer above the first sub-inner pattern layer.

6. The display device of claim 1, wherein the dummy layer comprises:
a first sub-dummy layer;
a second sub-dummy layer above the first sub-dummy layer;
a third sub-dummy layer above the second sub-dummy layer; and
a fourth sub-dummy layer above the third sub-dummy layer.

7. The display device of claim 6, wherein the first sub-dummy layer is at least partially above the outer pattern layer and the inner pattern layer.

8. The display device of claim 6, wherein the fourth sub-dummy layer is above the outer pattern layer and the inner pattern layer.

9. The display device of claim 1, wherein the through hole and the inner pattern layer have a same shape.

10. The display device of claim 1, the dummy layer has a through hole overlapping the inner pattern layer.

11. An optical device comprising:
an optical-path-changing member; and
a display device below the optical-path-changing member, and comprising:
a substrate;
a first electrode above the substrate;
a pixel-defining layer above the first electrode;
a light-emitting stack above the first electrode and the pixel-defining layer;
a second electrode above the light-emitting stack; and
an align key in a non-display area of the substrate, and comprising:
an outer pattern layer above the substrate;
an inner pattern layer inside a through hole of the outer pattern layer; and
a dummy layer between the outer pattern layer and the inner pattern layer.

12. The optical device of claim 11, wherein the outer pattern layer and the inner pattern layer comprise metal, and
wherein the dummy layer comprises a non-metal.

13. The optical device of claim 11, wherein the inner pattern layer is surrounded by the outer pattern layer in plan view.

14. The optical device of claim 11, wherein the outer pattern layer comprises:
a first sub-outer pattern layer; and
a second sub-outer pattern layer above the first sub-outer pattern layer.

15. The optical device of claim 11, wherein the inner pattern layer comprises:
a first sub-inner pattern layer; and
a second sub-inner pattern layer above the first sub-inner pattern layer.

16. The optical device of claim 11, wherein the dummy layer comprises:
a first sub-dummy layer;
a second sub-dummy layer above the first sub-dummy layer;
a third sub-dummy layer above the second sub-dummy layer; and
a fourth sub-dummy layer above the third sub-dummy layer.

17. The optical device of claim 16, wherein the first sub-dummy layer is at least partially above the outer pattern layer and the inner pattern layer.

18. The optical device of claim 16, wherein the fourth sub-dummy layer is above the outer pattern layer and the inner pattern layer.

19. The optical device of claim 11, wherein the through hole and the inner pattern layer have a same shape.

20. An electronic device comprising:
a display device comprising:
a screen;
a substrate;
a first electrode above the substrate;
a pixel-defining layer above the first electrode;
a light-emitting stack above the first electrode and the pixel-defining layer;
a second electrode above the light-emitting stack; and
an align key in a non-display area of the substrate, and comprising:
an outer pattern layer above the substrate;
an inner pattern layer inside a through hole of the outer pattern layer; and
a dummy layer between the outer pattern layer and the inner pattern layer.
